(19) United States
(12) Patent Application Publication
(10) Pub. No.: US 2013/0288474 A1
(43) Pub. Date: Oct. 31, 2013

(54) METHODS FOR FABRICATING DUAL DAMASCENE INTERCONNECT STRUCTURES

(71) Applicants: ROHIT MISHRA, Santa Clara, CA (US); JAYAGATAN R. VIJAYEN, Sunnyvale, CA (US); KHALID M. SIRAJUDDIN, San Jose, CA (US); BRAD EATON, Menlo Park, CA (US); MADHAVA RAO YALAMANCHILI, Morgan Hill, CA (US)

(72) Inventors: ROHIT MISHRA, Santa Clara, CA (US); JAYAGATAN R. VIJAYEN, Sunnyvale, CA (US); KHALID M. SIRAJUDDIN, San Jose, CA (US); BRAD EATON, Menlo Park, CA (US); MADHAVA RAO YALAMANCHILI, Morgan Hill, CA (US)

(73) Assignee: APPLIED MATERIALS, INC., Santa Clara, CA (US)

(21) Appl. No.: 13/458,172

(22) Filed: Apr. 27, 2012

(51) Int. Cl. H01L 21/768

(52) U.S. Cl. 438/637; 257/E21.586

(57) ABSTRACT

Methods for fabricating dual damascene interconnect structures are provided herein. In some embodiments, a method for fabricating a dual damascene interconnect structure may include etching a via into a substrate through a first photoresist layer; patterning a second photoresist layer atop the substrate to define a trench pattern, wherein the via is aligned within the trench pattern, and wherein a portion of undeveloped photoresist remains in the via after patterning; and etching the trench into the substrate to form a dual damascene pattern in the substrate.

### FIELD

Embodiments of the present invention generally relate to substrate processing, and more particularly, to methods for forming dual damascene interconnect structures in a substrate.

### BACKGROUND

Dual damascene interconnect structures are used to create multi-level, high density metal interconnections needed for advanced, high performance integrated circuits (ICs). In one application, dual damascene processing is used for creating connections in through silicon via (TSV) interposers used as an electrical interface to reroute connections, for example from an IC die, to a different connection, for example to a packaging substrate to which the IC is connected.

Etching dual damascene interconnect structures involves patterning a dielectric layer, such as silicon oxide, to have trenches and vias that may be simultaneously filled with a metal to create the electrical connections from one side of the interposer to the other. Dual damascene processing includes a plurality of steps, each of which contributes to the cost of production of the completed structure. In conventional dual damascene processing, a protective coating called a bottom anti reflective coating, or BARC, is typically deposited within the via prior to patterning and etching the trench in order to protect an underlying etch stop layer. Protecting the etch stop layer in the via during the trench etch is important to avoid exposing and etching underlying copper.

The inventors have provided an improved method of fabricating dual damascene interconnect structures.

### SUMMARY

Methods for fabricating dual damascene interconnect structures are provided herein. In some embodiments, a method for fabricating a dual damascene interconnect structure may include etching a via into a substrate through a first photoresist layer; patterning a second photoresist layer atop the substrate to define a trench pattern, wherein the via is aligned within the trench pattern, and wherein a portion of undeveloped photoresist remains in the via after patterning; and etching the trench into the substrate to form a dual damascene pattern in the substrate.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a flow chart of a method of fabricating a dual damascene structure in accordance with some embodiments of the present invention.

FIGS. 2A-F schematically depict stages of fabrication of a dual damascene structure in accordance with FIG. 1.

FIG. 3 depicts a schematic side view of an etch reactor suitable to perform portions of the methods of fabricating dual damascene structures in accordance with some embodiments of the present invention.

FIG. 4 depicts a simplified side view of a flip chip integrated circuit coupled to an underlying printed circuit board (PCB) via an interposer substrate having one or more dual damascene structures in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

The present invention provides embodiments of methods for fabricating dual damascene structures. In some illustrative embodiments, such dual damascene structures may be used in high aspect ratio applications, such as through silicon via (TSV) applications. In some illustrative embodiments, such dual damascene structures may be used in a TSV interposer application. Embodiments of the present invention may advantageously provide faster and less expensive methods of fabricating dual damascene structures as compared to prior art methods that use additional protective layers such as bottom anti-reflective coatings (BARC) during the fabrication sequence.

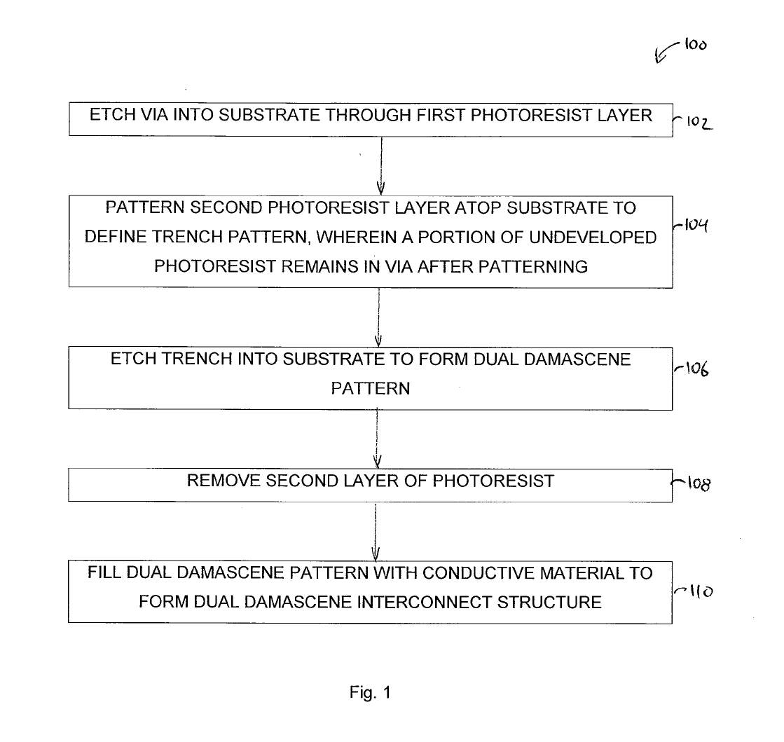

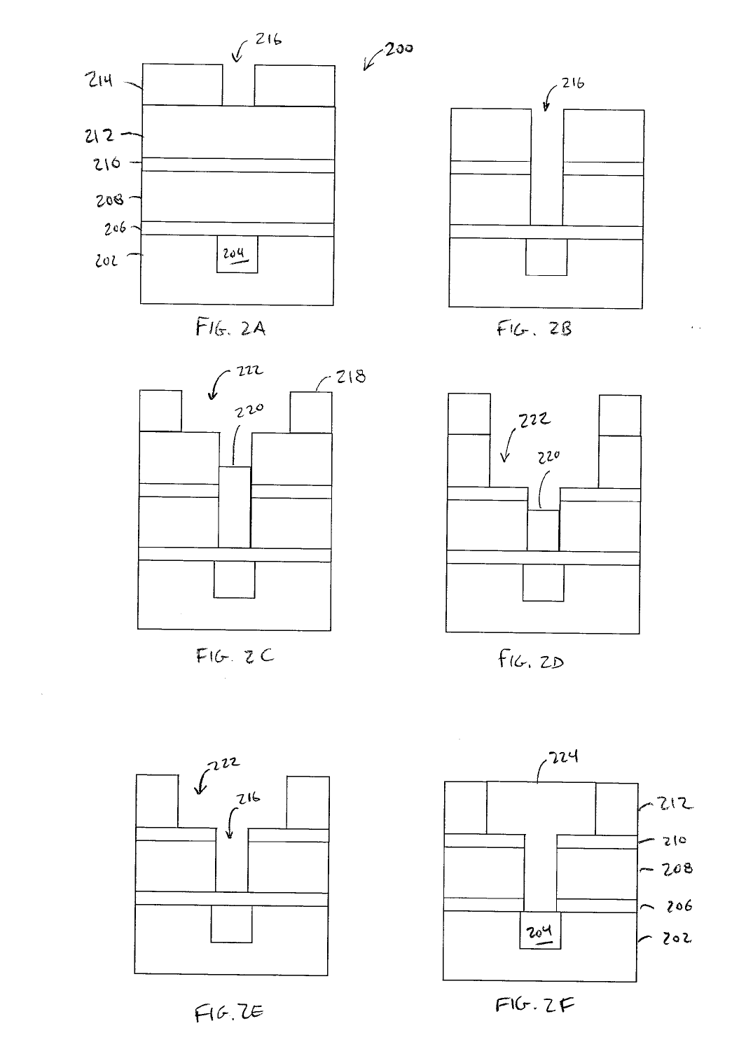

FIG. 1 is a flow chart of a method 100 of fabricating a dual damascene structure in accordance with some embodiments of the present invention. FIGS. 2A-F schematically depict stages of fabrication of a dual damascene structure in accordance with the method 100 of FIG. 1.

The method 100 generally begins at 102, where a via 216 is etched into a substrate 200 through a first photoresist layer 214. The substrate 200 may be any suitable substrate, such as a round semiconductor wafer. Substrates having other geometries, such as rectangular, polygonal, or other geometric configurations may also be used. Also, substrates comprising other materials may also be used. The substrate may include one or more additional layers formed thereon. In some embodiments, the substrate 200 may be an interposer substrate for use as an electrical interface to reroute connections, for example from an IC die, to a different connection, for example to a packaging substrate to which the IC is connected.

In some embodiments, the substrate may include a plurality of layers formed thereon. For example, as illustrated in FIGS. 2A-F, the substrate 200 may include a first dielectric layer 202 having a conductor 204 disposed in the first dielectric layer 202. A first surface of the conductor 204 is not covered by the first dielectric layer 202 such that the first surface of the conductor 204 and a first surface of the first dielectric layer 202 are substantially coplanar. A first etch stop layer 206 is disposed atop the first dielectric layer 202 and the conductor 204. A second dielectric layer 208 is disposed atop the first etch stop layer 206. A second etch stop layer 210 may be disposed atop the second dielectric layer 208. A third dielectric layer 212 may be disposed atop the second etch stop layer 210. In some embodiments, when the second etch stop layer 210 is not present, the third dielectric layer 212 may be disposed directly atop the second dielectric layer 208, or may be omitted completely and the second dielectric layer 208 may be formed to a thickness suitable to fabricate the dual damascene structure within the second dielectric layer 208.

In some embodiments, the first dielectric layer 202 may comprise silicon (Si). In some embodiments, the second dielectric layer 208 and the third dielectric layer 212 may comprise silicon oxide (SiO₂). In some embodiments, the conductor 204 may comprise copper (Cu). In some embodiments, the first etch stop layer 206 and the second etch stop layer 210 may comprise silicon nitride (Si₃N₄), silicon carbide (SiC), doped silicon carbide films, such as a Barrier Low-K dielectric film (BLOK™), or the like. BLOK™ is a silicon carbide film that may be formed using the chemical vapor deposition (CVD) or plasma enhanced CVD process described in commonly owned U.S. Pat. No. 6,287,990 B1, issued Sep. 11, 2001, and U.S. Pat. No. 6,303,523 B2, issued Oct. 16, 2001.

The first photoresist layer 214 may be deposited and patterned in any suitable manner to define the pattern of the via 216 to be etched into the substrate 200, as depicted in FIG. 2A. In some embodiments, the via 216 may be etched through the third dielectric layer 212, through the second etch stop layer 210, and through the second dielectric layer 208, until the first etch stop layer 206 is reached, as depicted in FIG. 2B. In embodiments where no second etch stop layer 210 is present, the via 216 may be etched through the third dielectric layer 212, if present, and the second dielectric layer 208 until the first etch stop layer 206 is reached.

The via 216 may be etched into the substrate (e.g., through the third dielectric layer 212 and/or the second dielectric layer 208) using any suitable etch process (e.g., an etch process suitable for etching the second and third dielectric layers 208, 212 with selectivity against the first etch stop layer 206). For example, in embodiments where the third dielectric layer 212 comprises silicon oxide, an etchant species such as carbon tetrafluoride (CF₄), CHF₃, C₄F₈, C₄F₆, CH₂F₂, NF₃, SF₆, or the like may be provided to etch the via 216. The etch process may be performed for a predetermined period of time calculated to complete or substantially complete the etch process, or endpoint detection techniques may be used to detect the transition from etching the third dielectric layer 212 to etching the first etch stop layer 206. Upon completion of etching the via 216, any remaining photoresist from the first photoresist layer 214 may be removed, for example, by ashing or the like. Although not meant to be limiting of the scope of the invention, in some embodiments, the via may be etched to a depth of about 1 to about 10 micrometers, or, in some embodiments, about 2 to about 5 micrometers.

Next, at 104, a second photoresist layer 218 may be disposed and patterned atop the substrate 200 to define a pattern for a trench 222. The second photoresist layer 218 is exposed and developed in such a manner as to leave a portion of undeveloped photoresist 220 in the via 216 after patterning the second photoresist layer 218. The portion of undeveloped photoresist 220 in the via 216 advantageously covers the first etch stop layer 206 and prevents etching through the first etch stop layer 206 when etching the trench 222, which would undesirably expose and possibly etch the underlying conductor 204. Exposing and/or etching the conductor 204 may lead to poor electrical coupling of the conductor to a subsequent conductive material used to fill the via 216 leading to poor device performance or failure. The etched conductive material may also undesirably contaminate the substrate and/or the process chamber, leading to further quality problems or device failures.

Conventionally, the first etch stop layer 206 is covered with a separately deposited layer of material (e.g., a bottom anti-reflective coating, or BARC) before or after patterning the trench. However, such additional deposition of material undesirably provides a higher capital cost from the added step and the cost of consumables for depositing the material. During the lithographic process for patterning the second photoresist layer 218 to define the trench 222, a dose of light exposure can be controlled to leave residual photoresist inside the via 216. The residual photoresist protects the first etch stop layer 206 similar to the BARC fill layer, however, without the extra added step of BARC fill. Thus, by altering the photoresist development and exposure process such that sufficient photoresist remains in the via 216 to protect the first etch stop layer 206 when etching the trench 222, the present invention advantageously reduces the time and materials cost of production without any loss of quality or risk of contamination of process equipment. In addition, the photoresist remaining in the via 216 further advantageously protects the via 216 from flaring while etching the trench (e.g., from being etched disproportionately near the via opening).

The amount of photoresist left in the via 216 may be controlled by controlling the dose of the light that the photoresist is exposed to during the photoresist exposure stage. Providing a smaller dose of light reduces the activation of the photoresist, allowing some photoresist to remain unexposed and in the via after development. For example, in some embodiments, and depending upon the dimensions of the via, after a high trench pattern exposure (for example, 200 mJ/cm2), the photoresist may be fully exposed and no residual photoresist remains in the via after developing the photoresist. With sufficient exposure dose, light travels deeper into the via, photo-activating photoresist all the way to the bottom of the via, which later gets removed during photoresist developing. With lower doses (for example, 90 mJ/cm2), the light does not reach to the bottom of the via and therefore unexposed photoresist remains in the via which gets left behind after the photoresist developing step. The trench pattern photoresist exposure dose can be controlled to control the amount of photoresist that remains in the via after exposure. In some embodiments, the remaining photoresist in the via may occupy up to about 90 percent of the depth of the via, or between about 10 to about 90 percent of the depth of the via.

Next, at 106, the trench 222 may be etched into the substrate 200 to form a dual damascene pattern in the substrate 200.

The trench 222 may be etched into the substrate (e.g., through the third dielectric layer 212) using any suitable etch process, such as any of the etch process discussed above with respect to etching the via 216. The etch process may be performed for a predetermined period of time calculated to complete or substantially complete the etch process, or endpoint detection techniques may be used to detect the transition from etching the third dielectric layer 212 to etching the second etch stop layer 208.

Next, at 108, upon completion of etching the trench 222, any remaining photoresist from the second photoresist layer 218, including the portion 220 in the via 216, may be removed, for example, by ashing or the like.

Next, at 110, the dual damascene pattern (e.g., the trench 222 and the via 216) may be filled with a conductive material 224 to form the dual damascene interconnect structure. The conductive material may be the same or, in some embodiments, a different, material as the conductor 204. In some embodiments, the conductive material is copper. The conductive material may be deposited within the dual damascene pattern using any suitable technique such as plating, chemical vapor deposition (CVD), physical vapor deposition (PVD), or the like. In some embodiments, one or more layers, such as a liner and/or barrier layer (for example, titanium, tantalum, or nitrides thereof) and/or a seed layer (for example, copper), may be deposited in the dual damascene structure prior to filling the dual damascene patter with the conductive material 224. In some embodiments, additional processing, such as a chemical mechanical planarization (CMP) process may be performed to remove any overfill of the conductive material atop the substrate 200.

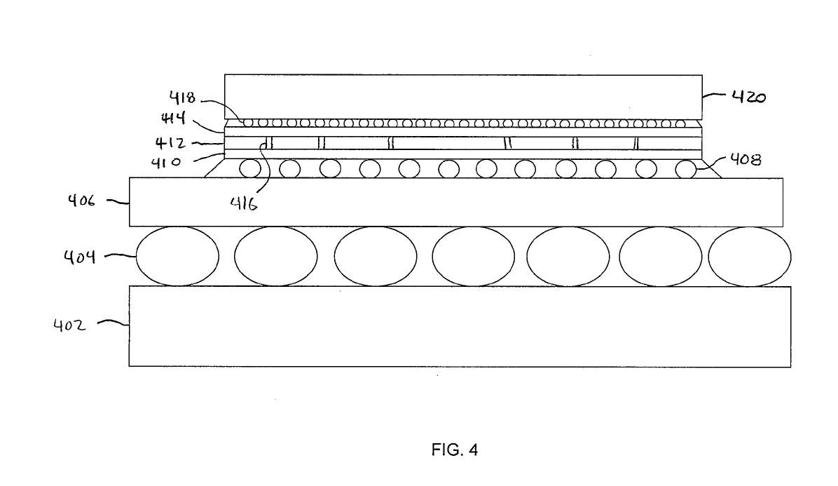

Although described above in one exemplary application, the inventive methods described herein may also be used in other applications. For example, FIG. 4 depicts a simplified side view of a flip chip integrated circuit (flip chip 420) coupled to an underlying printed circuit board (PCB) 402 via an interposer substrate 412 having one or more dual damascene structures in accordance with some embodiments of the present invention. The PCB 402 has a plurality of contact pads upon which conductors (e.g., balls 404) are disposed to couple the PCB 402 to an intermediate substrate 406. The typical spacing, or pitch, between adjacent balls on the BCP 402 is about 0.4-0.5 mm. The intermediate substrate 406 may be a flip-chip ball grid array (FC-BGA) substrate or a high density interconnect (HDI) substrate or the like. The intermediate substrate 406 typically only reduces the pitch between adjacent conductors to as small as about 180 micrometers. A second plurality of balls 408 are disposed on the opposite side of the intermediate substrate 406 as the PCB 402 to couple the intermediate substrate 406 to an interposer substrate 412. The typical pitch between adjacent ones of the second plurality of balls 408 is typically 100-200 micrometers.

The interposer substrate 412 may have dual damascene structures formed as described above to redistribute the electrical connections between the second plurality of balls 408 on the intermediate substrate 406 and a third plurality of balls 418 that couple the interposer substrate 412 to the flip chip 420. The third plurality of balls, sometimes referred to as microbumps, may have even smaller pitch than the second plurality of balls. In some embodiments, the interposer substrate 412 may be a silicon substrate and may have one or more dielectric layers 410 disposed on a first side of the interposer 412 and one or more dielectric layers 414 disposed on a second side of the interposer 412 opposite the first side. The dielectric layers may be similar to any of the dielectric layers disclosed above with respect to FIGS. 1-2. A plurality of through silicon vias (TSV) 416 facilitate coupling the conductive pathways formed on either side of the interposer 412. Dual damascene structures may be formed in either or both of the dielectric layers 410, 414 in the manner as discussed above. Each TSV 416 may be part of the dual damascene structure or aligned with the via portion of the dual damascene structure.

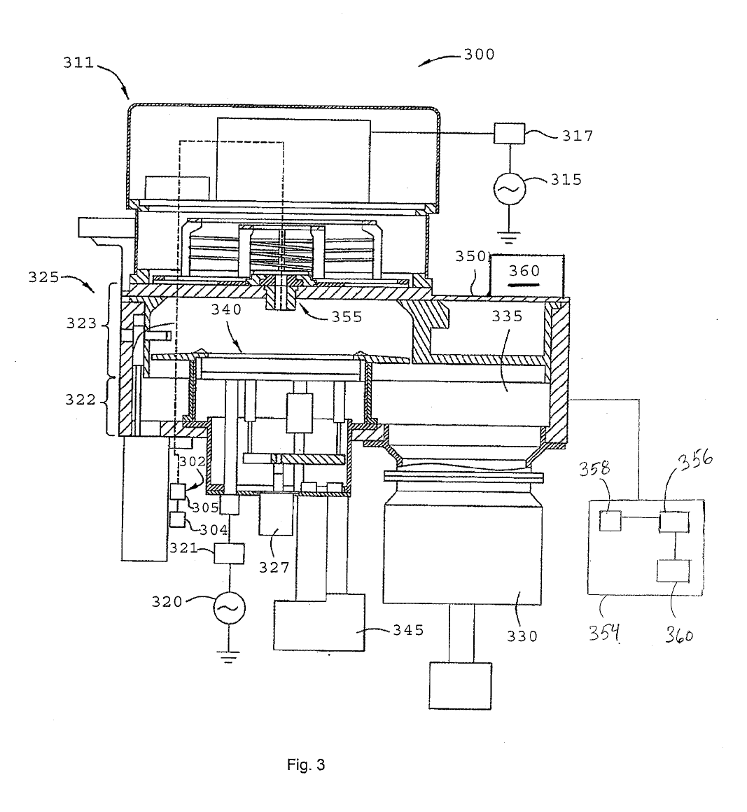

FIG. 3 illustrates a sectional side view of a system, such as a reactor 300, suitable for processing a variety of substrates and accommodating a variety of substrate sizes in accordance with at least portions, such as the etching processes discussed above, of embodiments of the present invention. In some embodiments, the substrate may be a round wafer, such as a 200 or 300 mm diameter, or larger, such as 450 mm. The substrate can also be any polygonal, square, rectangular, curved or otherwise non-circular workpiece, such as a polygonal glass substrate used in the fabrication of flat panel displays. The reactor 300 may be part of an Applied Centura® Silvia™ Etch system, commercially available from Applied Materials, Inc. of Santa Clara, Calif. Other reactors available from other manufacturers may also be utilized to practice portions of the present invention.

In some embodiments, the reactor 300 may include a source power 315 and a matching network 317, a bias power 320 and a matching network 321, a chamber 325, a pump 330, a valve 335, an electrostatic chuck 340, a chiller 345, a lid 350, a gas nozzle 355, and a gas delivery system 302.

In some embodiments, the gas delivery system 302 is located in a housing 305 disposed directly adjacent, such as under, the chamber 325. The gas delivery system 302 selectively couples one or more gas sources located in one or more gas panels 304 to the gas nozzle 355 to provide process gases to the chamber 325. The housing 305 is located in close proximity to the chamber 325 to reduce gas transition time when changing gases, minimize gas usage, and minimize gas waste.

The reactor 300 may further include a lift 327 for raising and lowering the chuck 340 that supports a substrate in the chamber 325. The chamber 325 further includes a body having a lower liner 322, an upper liner 323, and a door for entry and egress of a substrate. The valve 335 may be disposed between the pump 330 and the chamber 325 and may be operable to control pressure within the chamber 325. The ceramic electrostatic chuck 340 may be disposed within the chamber 325. The lid 350 may be disposed on the chamber 325.

The gas nozzle 355 may comprise a tunable gas nozzle having one or more outlets to selectively direct gas flow from the gas delivery system 302 to the chamber 325. The gas nozzle 355 may be operable to direct gas flow into different areas within the chamber 325, such as the center area and/or the side areas of the chamber 325. In some embodiments, the gas nozzle 355 may include a first outlet that introduces gases from the top of the chamber 325 and a second outlet that introduces gases from the side of the chamber 325 to selectively control the distribution of the gases in the chamber 325.

The gas delivery system 302 may be used to supply at least two different gas mixtures to the chamber 325 at an instantaneous rate as further described below. In an optional embodiment, the reactor 300 may include a spectral monitor operable to measure the depth of an etched trench and a deposited film thickness as the trench is being formed in the chamber 325, with the ability to use other spectral features to determine the state of the reactor. The reactor 300 may be configured to accommodate a variety of substrate sizes, for example a substrate diameter of up to about 300 mm (although larger or smaller sized substrates may be used in reactors having other configurations). In operation, and as will be discussed herein, the reactor 300 is configurable to produce etched substrate trench sidewall profiles having angles that taper in a range of about 85 degrees to about 92 degrees, and etched substrate trenches having depths that range from about 10 micrometers to about 500 micrometers.

In some embodiments, the source power 315 for generating and maintaining the plasma processes is coupled to the chamber 325 via a power generating apparatus enclosed in a housing 311 disposed above the chamber 325. The source power may be an inductively coupled source power. The source power 315 may be operable to generate a radio frequency within a range from about 2 MHz to about 13.5 MHz, having pulsing capabilities, a power within a range from about 10 watts to about 10,000 watts, for example, from about 4,500 watts to about 5,500 watts and may further include a dynamic matching network 317. In one example, the source power 315 may be operable to generate a 13 MHz radio frequency having pulsing capabilities. The source power 315 may comprise a dual tunable source so that the radio frequency may be changed during an etching cycle. In some embodiments, the source power 315 may comprise a remote plasma source capable of generating high levels of plasma disassociation that is mountable to the reactor 300. When using a remote plasma source, the reactor 300 may further include a plasma distribution plate or series of plates disposed in the chamber 325 to help distribute the plasma to the substrate. In some embodiments, the reactor 300 may include both an in-situ source power and a remote plasma source power, wherein the plasma is generated in a remote plasma chamber using the remote plasma source power and transferred to the reactor chamber 325, wherein the in-situ source power 315 maintains the generated plasma within the chamber 325. In some embodiments, an etching cycle may be performed wherein the power range, i.e. the wattage of the power source 315, may be increased or decreased during the etching cycle. The source power 315 may be pulsed during the etching cycle.

In some embodiments, the bias power 320 for biasing the substrate is coupled to the chamber 325 and the chuck 340. The bias power 320 may be operable to generate a radio frequency of about 400 KHz having pulsing capabilities, a low power range from about 10 watts to about 2000 watts, for example, from about 900 to about 1800 watts, and may further include a dynamic matching network 321. In some embodiments, the bias power 320 may be capable of generating a selectable radio frequency range from about 100 kHz to about 13.56 MHz, from about 100 kHz to about 2 MHz, and from about 400 kHz to about 2 MHz, having pulsing capabilities, a low power range from about 10 watts to about 2,000 watts, and may further include a dynamic matching network or a fixed matching network and a frequency tuner. In some embodiments, an etching cycle may be performed wherein the power range, i.e. the wattage of the bias power 320, may be increased or decreased during the etching cycle.

The bias power 320 may be pulsed during the etching cycle. To pulse the bias power 320, the radio frequency power is switched on and off during the etching cycle. The pulsing frequency of the bias power 320 may range from about 10 Hz to about 1,000 Hz, and may range from about 50 Hz to about 180 Hz. In some embodiments, the switching of the power on and off is uniformly distributed in time throughout the etching cycle. In some embodiments, the timing profile of the pulsing may be varied throughout the etching cycle, and may depend on the composition of the substrate. The percentage of time the bias power 320 is switched on, i.e. the duty cycle as described above, is directly related to the pulsing frequency. In some embodiments, when the pulsing frequency ranges from about 10 Hz to about 1000 Hz, the duty cycle ranges from about 30% to about 90%. The bias power frequency and the pulsing frequency may be adjusted depending on the substrate material being processed.

In some embodiments, the chiller 345 may be operable to control the temperature within the chamber 325 and of the substrate located within the chamber 325. The chiller 345 may be located near and coupled to chamber 325. The chiller 345 may include a low temperature chiller, such as a sub-zero point of use thermo-electric chiller, and may further include a direct cooling mechanism for ultra lower temperatures. The chiller 345 is operable to generate temperatures in the range of about −20 degrees to about 80 degrees Celsius, located near the chamber 325 to achieve a faster reaction time, and may include ramping capabilities to allow some level of control to help improve the etch rate. In some embodiments, the chiller 345 is capable of generating temperatures in the range of about −10 degrees to about 60 degrees Celsius and may be located near the chamber 325 to achieve a faster reaction time. In some embodiments, the chiller 345 may be operable to lower the temperature from about −10 degrees Celsius to about −20 degrees Celsius in the chamber 325.

In certain embodiments, the reactor 300 may include an additional cooling mechanism 360 for controlling the temperature of the reactor 300. The additional cooling mechanism 360 may be positioned on the lid 355 to control the temperature of the lid 355 which may exhibit an increased temperature due to the use of the increased source power. The additional cooling mechanism 360 may comprise one or more high cooling capacity fans.

In some embodiments, the reactor 300 is operable to maintain a chamber pressure range of about 10 mTorr to about 1,000 mTorr with the pump 330 and the valve 335, which is coupled to the chamber 325. The chamber pressure can be adjusted during the etching cycle to further improve the trench profiles. For example, the chamber pressure may be rapidly decreased or increased when switching from the deposition step to the etch step. The pump 330 may comprise a turbo pump, a 2,600 L/s turbo pump for example, operable to process flows in the range of about 100 sccm to about 1,000 sccm throughout the chamber 325. In conjunction with the pump 330, the valve 335 may comprise a throttling gate valve with a fast reaction time to help control the process flow and the pressure changes. The reactor 300 may further include a dual manometer to measure the pressure in the chamber 325. In some embodiments, the reactor 300 is operable to maintain a dynamic pressure in the range of about 10 mTorr to about 250 mTorr, for example, from about 60 to about 150 mTorr, during the etching cycle. Optionally, an automatic throttling gate valve control or a valve with preset control points may be utilized, and the dynamic pressure may be sustained at a set-point while changing flow parameters.

In some embodiments, a controller 354 comprises a central processing unit (CPU) 356, a memory 358, and support circuits 360 for the CPU 356 facilitates control of the components of the reactor 300 and, as such, of the etch process, as discussed below in further detail. To facilitate control of the reactor 300, the controller 354 may be one of any form of general-purpose computer processor that can be used in an industrial setting for controlling various chambers and sub-processors. The memory 358, or computer-readable medium, of the CPU 356 may be one or more of readily available memory such as random access memory (RAM), read only memory (ROM), floppy disk, hard disk, or any other form of digital storage, local or remote. The support circuits 360 are coupled to the CPU 356 for supporting the processor in a conventional manner. These circuits include cache, power supplies, clock circuits, input/output circuitry and subsystems, and the like. The inventive methods described herein, or at least portions thereof (e.g., portions performed in the reactor 300, or portions performed by equipment controlled by the controller 354), may be stored in the memory 358 as a software routine. The software routine may also be stored and/or executed by a second CPU (not shown) that is remotely located from the hardware being controlled by the CPU 356.

While the foregoing is directed to embodiments of the present invention, other and further embodiments of the invention may be devised without departing from the basic scope thereof.

1. A method of fabricating a dual damascene interconnect structure, comprising:
etching a via into a substrate through a first photoresist layer;
patterning a second photoresist layer atop the substrate to define a trench pattern, wherein the via is aligned within the trench pattern, and wherein a portion of undeveloped photoresist remains in the via after patterning; and
etching the trench into the substrate to form a dual damascene pattern in the substrate.

2. The method of claim 1, further comprising:
removing the second layer of photoresist; and
filling the dual damascene pattern with a conductive material to form a dual damascene interconnect structure.

3. The method of claim 1, wherein the via is disposed completely through the substrate.

4. The method of claim 1, wherein the via is aligned with and is coupled to a conductor disposed within the substrate.

5. The method of claim 1, wherein the substrate comprises silicon having one or more dielectric layers disposed atop the silicon, and wherein the dual damascene pattern is formed in the one or more dielectric layers.

6. The method of claim 5, wherein the one or more dielectric layers comprise silicon oxide.

7. The method of claim 6, wherein etching the via into the substrate comprises etching the one or more one or more dielectric layers using one or more of CF₄, CHF₃, C₄F₈, C₄F₆, CH₂F₂, NF₃, or SF₆.

8. The method of claim 1, wherein patterning the second photoresist layer comprises controlling a dose of light during an exposure of the second photoresist layer to prevent a portion of photoresist disposed in the via from being photo-activated and removed during a development of the second photoresist layer.

9. The method of claim 1, wherein the portion of undeveloped photoresist remains in the via after patterning fills up to about 90 percent of the via.

10. The method of claim 1, wherein the portion of undeveloped photoresist remains in the via after patterning fills about 10 to about 90 percent of the via.

11. The method of claim 1, wherein the substrate comprises a silicon interposer substrate to couple a flip chip integrated circuit coupled to an underlying printed circuit board.

12. The method of claim 11, wherein the substrate further comprises:
one or more dielectric layers disposed on a first side of the silicon interposer substrate; and
one or more dielectric layers disposed on a second side of the silicon interposer substrate opposite the first side.

13. The method of claim 12, wherein the dual damascene interconnect structure is formed in the one or more dielectric layers disposed on the first side of the silicon interposer substrate, and further comprising:
forming one or more second dual damascene interconnect structures in the one or more dielectric layers disposed on the second side of the silicon interposer substrate.

14. The method of claim 14, further comprising:
providing one or more through silicon vias in the silicon interposer substrate to couple at least one of the dual damascene interconnect structures to at least one of the second dual damascene interconnect structures.

15. The method of claim 1, wherein the substrate comprises a first dielectric layer having a conductor disposed in the first dielectric layer, wherein the via is aligned with the conductor.

16. A computer readable medium, having instructions stored thereon that, when executed, cause a method of method of fabricating a dual damascene interconnect structure to be performed, the method comprising:
etching a via into a substrate through a first photoresist layer;
patterning a second photoresist layer atop the substrate to define a trench pattern, wherein the via is aligned within the trench pattern, and wherein a portion of undeveloped photoresist remains in the via after patterning; and
etching the trench into the substrate to form a dual damascene pattern in the substrate.

17. The computer readable medium of claim 16, the method further comprising:
removing the second layer of photoresist; and
filling the dual damascene pattern with a conductive material to form a dual damascene interconnect structure.

18. The computer readable medium of claim 16, wherein etching the via into the substrate comprises either:
etching the via completely through the substrate; or
etching the via in alignment with a conductor disposed within the substrate beneath the via.

19. The computer readable medium of claim 16, wherein etching the via into the substrate comprises etching one or more one or more dielectric layers of the substrate using one or more of CF₄, CHF₃, C₄F₈, C₄F₆, CH₂F₂, NF₃, or SF₆.

20. The computer readable medium of claim 16, wherein patterning the second photoresist layer comprises controlling a dose of light during an exposure of the second photoresist layer to prevent a portion of photoresist disposed in the via from being photo-activated and removed during a development of the second photoresist layer.
